(19) United States
(12) Patent Application Publication
(10) Pub. No.: US 2026/0059976 A1
(43) Pub. Date: Feb. 26, 2026

(54) DISPLAY PANEL AND MANUFACTURING METHOD THEREFOR, AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Dongjie WU, Beijing (CN); Kai ZHANG, Beijing (CN); Erlong SONG, Beijing (CN); Hailong YAN, Beijing (CN); Fan ZHANG, Beijing (CN); Kunyan SHI, Beijing (CN); Qiang FU, Beijing (CN); Heng LI, Beijing (CN); Huaping SUN, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 19/102,574

(22) PCT Filed: Apr. 29, 2024
(86) PCT No.: PCT/CN2024/090661

§ 371 Date: Feb. 10, 2025

(30) Foreign Application Priority Data
May 31, 2023 (CN) 202310640139.1

(51) Int. Cl. H10K 59/80; H10K 59/12; H10K 59/122; H10K 59/40

(52) U.S. Cl. CPC H10K 59/873; H10K 59/1201; H10K 59/122; H10K 59/40

(57) ABSTRACT

A display panel includes a substrate, an isolation pillar, a cathode layer located on the substrate, and an encapsulation layer located on a side of the cathode layer away from the substrate. The isolation pillar includes a first isolation pillar and a second isolation pillar that sequentially are stacked on the substrate. The first isolation pillar includes a first pillar body and a first extension layer that are sequentially stacked. The second isolation pillar includes a second pillar body and a second extension layer that are sequentially stacked. The cathode layer partially extends between the first extension layer and the substrate and is partially located on the second isolation pillar. The encapsulation layer partially extends between the first extension layer and the cathode layer and between the second extension layer and the first isolation pillar.

### CROSS-REFERENCE TO RELATED APPLICATIONS

This application is a national phase entry under 35 USC 371 of International Patent Application No. PCT/CN2024/090661, filed on Apr. 29, 2024, which claims priority to Chinese Patent Application No. 202310640139.1, filed on May 31, 2023, each are incorporated herein by reference in their entirety.

### TECHNICAL FIELD

The present disclosure relates to the field of display technologies, and in particular, to a display panel and a manufacturing method therefor, and a display apparatus.

### BACKGROUND

With the development of display technologies, display apparatuses (e.g., mobile phones, notebook computers or tablet computers) are increasingly used in people's lives. In comparison with conventional liquid crystal displays, active matrix organic light-emitting diode (AMOLED) displays are not only lighter and thinner, but also have good characteristics such as self-luminous, low power consumption, not requiring a backlight source, no limitation on viewing angle and fast response, and thus have become the mainstream of the next generation of flat panel display technology and are used more and more widely.

### SUMMARY

In an aspect, a display panel is provided. The display panel includes a display region, a through hole region and an isolation region, the isolation region surrounds the through hole region, the display region is adjacent to the isolation region, and a portion of the display panel that is located in the through hole region includes a through hole. The display panel includes a substrate, an isolation pillar, a cathode layer and an encapsulation layer. The isolation pillar is located on the substrate and located in the isolation region and surrounds the through hole region, and the isolation pillar includes a first isolation pillar and a second isolation pillar that are stacked in a first direction. The first isolation pillar is located between the substrate and the second isolation pillar. The first isolation pillar includes a first pillar body and a first extension layer that are stacked in the first direction; the first pillar body is located between the first extension layer and the substrate, an orthographic projection of the first pillar body on the substrate is located in an orthographic projection of the first extension layer on the substrate, and the first pillar body and the first extension layer are of a one-piece structure. The second isolation pillar includes a second pillar body and a second extension layer that are stacked in the first direction; the second pillar body is located between the second extension layer and the first isolation pillar, an orthographic projection of the second pillar body on the substrate is located in an orthographic projection of the second extension layer on the substrate, and the second pillar body and the second extension layer are of a one-piece structure. The cathode layer is located on the substrate and includes a first portion and a second portion; the first portion is located in the display region and the isolation region and partially extends between the first extension layer and the substrate, and the second portion is located on a side of the second isolation pillar away from the substrate. The encapsulation layer is located on a side of the cathode layer away from the substrate and located in the display region and the isolation region, wherein a portion of the encapsulation layer extends between the first extension layer and the cathode layer, and another portion of the encapsulation layer extends between the second extension layer and the first isolation pillar. The first direction is perpendicular to the substrate.

In some embodiments, the display panel further includes a first planarization layer located between the substrate and the cathode layer and located in the display region and the isolation region; the first planarization layer and the first isolation pillar are arranged in a same layer.

In some embodiments, the display panel further includes a second planarization layer located between the first planarization layer and the cathode layer and located in the display region and the isolation region; the second planarization layer and the second isolation pillar are arranged in a same layer.

In some embodiments, the display panel further includes a pixel defining layer located between the first planarization layer and the cathode layer and located in the display region and the isolation region; the pixel defining layer and the second planarization layer are arranged in a same layer.

In some embodiments, the display panel includes a plurality of isolation pillars, and the plurality of isolation pillars are arranged at intervals in a direction perpendicular to a border of the through hole.

In some embodiments, the display panel further includes a dam structure located in the isolation region and surrounding the through hole; at least one isolation pillar of the plurality of isolation pillars is located on a side of the dam structure proximate to the through hole, and another at least one isolation pillar of the plurality of isolation pillars is located on a side of the dam structure away from the through hole.

In some embodiments, the dam structure includes a third pillar body and a third extension layer that are stacked in the first direction, the third pillar body is located between the third extension layer and the substrate, and an orthographic projection of the third pillar body on the substrate is located in an orthographic projection of the third extension layer on the substrate; the second portion is further located on a side of the third extension layer away from the substrate.

In some embodiments, a thickness of an edge portion of the third extension layer is less than a thickness of a central portion of the third extension layer.

In some embodiments, the third extension layer includes a first sub-layer, a second sub-layer, a third sub-layer, and a fourth sub-layer that are stacked in the first direction; the first sub-layer is located between the second sub-layer and the third pillar body, and the third sub-layer is located between the second sub-layer and the fourth sub-layer; the orthographic projection of the third pillar body on the substrate is located in an orthographic projection of the first sub-layer on the substrate, the orthographic projection of the first sub-layer on the substrate is located in an orthographic projection of the second sub-layer on the substrate, and the orthographic projection of the second sub-layer on the substrate is located in an orthographic projection of the third sub-layer on the substrate.

In some embodiments, the third pillar body, the first sub-layer, and the first planarization layer are arranged in a same layer; the second sub-layer and the second planarization layer are arranged in a same layer; the third sub-layer and the pixel defining layer are arranged in a same layer; the display panel further includes a touch insulating layer, the touch insulating layer is located on a side of the encapsulation layer away from the substrate, and the fourth sub-layer and the touch insulating layer are arranged in a same layer.

In some embodiments, the display panel further includes an interlayer dielectric layer and a passivation layer that are stacked in the first direction; the passivation layer is located between the cathode layer and the interlayer dielectric layer.

The interlayer dielectric layer includes a blocking recess, the blocking recess is located in the isolation region, the passivation layer is partially located in the blocking recess, and a portion of the dam structure proximate to the substrate is located in the blocking recess and located on a side of the passivation layer away from the interlayer dielectric layer.

In some embodiments, the display panel further includes a first source-drain metal layer; the first source-drain metal layer is located between the passivation layer and the interlayer dielectric layer, and the first source-drain metal layer is partially located in the blocking recess.

In some embodiments, the display panel further includes a gate metal layer; the gate metal layer is located on a side of the interlayer dielectric layer away from the cathode layer, and the gate metal layer is partially located in the blocking recess.

In some embodiments, the encapsulation layer includes a first inorganic encapsulation layer, an organic encapsulation layer, and a second inorganic encapsulation layer that are stacked in the first direction, and the organic encapsulation layer is located between the first inorganic encapsulation layer and the second inorganic encapsulation layer; the display panel includes at least two dam structures, an orthographic projection of a dam structure of the at least two dam structures on the substrate is located in an orthographic projection of the organic encapsulation layer on the substrate, and another dam structure of the at least two dam structures abuts an edge of the organic encapsulation layer located in the isolation region.

In another aspect, a display apparatus is provided, which includes the display panel according to any one of the above embodiments and a cover plate, and the cover plate is located on a side of the isolation pillar of the display panel away from the substrate of the display panel.

In yet another aspect, a manufacturing method for a display panel is provided. The display panel includes a display region, a through hole region and an isolation region, the isolation region surrounds the through hole region, the display region is adjacent to the isolation region, and a portion of the display panel that is located in the through hole region includes a through hole; the manufacturing method for the display panel includes: providing a substrate; forming an isolation pillar, wherein the isolation pillar is located on the substrate and located in the isolation region and surrounds the through hole, the isolation pillar includes a first isolation pillar and a second isolation pillar that are stacked in a first direction, the first isolation pillar is located between the substrate and the second isolation pillar, and the first direction is perpendicular to the substrate; the first isolation pillar includes a first pillar body and a first extension layer that are stacked in the first direction, the first pillar body is located between the first extension layer and the substrate, an orthographic projection of the first pillar body on the substrate is located in an orthographic projection of the first extension layer on the substrate, and the first pillar body and the first extension layer are of a one-piece structure; the second isolation pillar includes a second pillar body and a second extension layer that are stacked in the first direction; the second pillar body is located between the second extension layer and the first isolation pillar, an orthographic projection of the second pillar body on the substrate is located in an orthographic projection of the second extension layer on the substrate, and the second pillar body and the second extension layer are of a one-piece structure; forming a cathode layer, wherein the cathode layer is located on the substrate and includes a first portion and a second portion, the first portion is located in the display region and the isolation region and partially extends between the first extension layer and the substrate, and the second portion is located on a side of the second isolation pillar away from the substrate; and forming an encapsulation layer, wherein the encapsulation layer is located on a side of the cathode layer away from the substrate and located in the display region and the isolation region, a portion of the encapsulation layer extends between the first extension layer and the cathode layer, and another portion of the encapsulation layer extends between the second extension layer and the first isolation pillar.

In some embodiments, forming the isolation pillar includes: forming a first sacrificial layer on the substrate, wherein the first sacrificial layer includes a first sacrificial block and a second sacrificial block that are spaced apart, the first sacrificial block and the second sacrificial block are both arranged surrounding the through hole, and the second sacrificial block is located on a side of the first sacrificial block away from the through hole region; forming the first isolation pillar, wherein the first pillar body is located between the first sacrificial block and the second sacrificial block, and the first extension layer is located on a side of the first sacrificial layer away from the substrate; forming a second sacrificial layer on a side of the first extension layer away from the substrate, wherein the second sacrificial layer includes a third sacrificial block and a fourth sacrificial block that are spaced apart, the third sacrificial block and the fourth sacrificial block are both arranged surrounding the through hole, and the fourth sacrificial block is located on a side of the third sacrificial block away from the through hole; and forming the second isolation pillar, wherein the second pillar body is located between the third sacrificial block and the fourth sacrificial block, and the second extension layer is located on a side of the second sacrificial layer away from the substrate.

In some embodiments, the manufacturing method for the display panel further includes: forming an interlayer dielectric layer, wherein the interlayer dielectric layer includes a blocking recess, and the blocking recess is located in the isolation region; and forming a first source-drain metal layer, wherein the first source-drain metal layer is located on the interlayer dielectric layer and partially located in the blocking recess, and the first source-drain metal layer and the first sacrificial layer are formed using a same patterning process.

In some embodiments, after providing the substrate, the manufacturing method for the display panel further includes: forming a third sacrificial layer on the substrate, wherein the third sacrificial layer includes a fifth sacrificial block and a sixth sacrificial block that are spaced apart, the fifth sacrificial block and the sixth sacrificial block are both arranged surrounding the through hole, and the sixth sacrificial block is located on a side of the fifth sacrificial block away from the through hole; forming a third pillar body, wherein the third pillar body is located between the fifth sacrificial block and the sixth sacrificial block; and forming a third extension layer, wherein the third extension layer is located on a side of the third sacrificial layer away from the substrate, an orthographic projection of the third pillar body on the substrate is located in an orthographic projection of the third extension layer on the substrate, and the third pillar body and the third extension layer constitute a dam structure.

In some embodiments, the manufacturing method for the display panel further includes: forming an interlayer dielectric layer, wherein the interlayer dielectric layer includes a blocking recess, and the blocking recess is located in the isolation region; forming a first source-drain metal layer, wherein the first source-drain metal layer is located on the interlayer dielectric layer and partially located in the blocking recess; forming a passivation layer, wherein the passivation layer is located on a side of the first source-drain metal layer away from the interlayer dielectric layer and partially located in the blocking recess; and forming the third pillar body includes: forming a portion of the third pillar body in the blocking recess.

### BRIEF DESCRIPTION OF THE DRAWINGS

In order to describe the technical solutions in the present disclosure more clearly, the accompanying drawings to be used in some embodiments of the present disclosure will be briefly introduced below. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a sectional view taken along the section line A-A in FIG. 1;

FIG. 3 is a structural diagram of a display panel, in accordance with some embodiments;

FIG. 4 is a sectional view of the display panel in FIG. 3 taken along the section line B-B;

FIG. 5 is a sectional view of a display panel, in accordance with some examples;

FIG. 6 is an electron microscope picture of a display panel, in accordance with some examples;

FIG. 7 is a schematic diagram illustrating peeling of film layers, in accordance with some examples;

FIG. 8 is an electron microscope picture of a display panel, in accordance with some other examples;

FIG. 9 is a sectional view of the display panel in FIG. 3 taken along the section line B′-B′;

FIG. 10 is a structural diagram of an isolation pillar, in accordance with some embodiments;

FIG. 11 is a structural diagram of a display panel, in accordance with some other embodiments;

FIG. 12 is a structural diagram of a dam structure, in accordance with some embodiments;

FIG. 13 is a structural diagram of a display panel, in accordance with still some other embodiments;

FIG. 14 is a structural diagram of a first sacrificial layer formed by a manufacturing method for a display panel, in accordance with some embodiments;

FIG. 15 is a structural diagram of a first isolation pillar formed by a manufacturing method for a display panel, in accordance with some embodiments;

FIG. 16 is a structural diagram of a second sacrificial layer formed by a manufacturing method for a display panel, in accordance with some embodiments;

FIG. 17 is a structural diagram of a second structural pillar formed by a manufacturing method for a display panel, in accordance with some embodiments;

FIG. 18 is a structural diagram of an isolation pillar formed by a manufacturing method for a display panel, in accordance with some embodiments;

FIG. 19 is a structural diagram of a third sacrificial layer formed by a manufacturing method for a display panel, in accordance with some embodiments;

FIG. 20 is a structural diagram of a first sub-layer formed by a manufacturing method for a display panel, in accordance with some embodiments;

FIG. 21 is a structural diagram of a second sub-layer formed by a manufacturing method for a display panel, in accordance with some embodiments;

FIG. 22 is a structural diagram of a third sub-layer and a fourth sub-layer formed by a manufacturing method for a display panel, in accordance with some embodiments;

FIG. 23 is a structural diagram of a dam structure formed by a manufacturing method for a display panel, in accordance with some embodiments;

FIG. 24 is a flow diagram of a manufacturing method for a display panel, in accordance with some embodiments;

FIG. 25 shows flow diagrams each illustrating a manufacturing method for a display panel, in accordance with some other embodiments; and

FIG. 26 is a flow diagram of a manufacturing method for a display panel, in accordance with still some other embodiments.

### DETAILED DESCRIPTION

The technical solutions in some embodiments of the present disclosure will be clearly and completely described below in conjunction with the accompanying drawings. Obviously, the embodiments to be described are merely some but not all embodiments of the present disclosure. All other embodiments obtained by a person of ordinary skill in the art based on the embodiments of the present disclosure should belong to the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, the terms “first” and “second” are used for descriptive purposes only, and are not to be construed as indicating or implying a relative importance or implicitly indicating the number of indicated technical features. Thus, a feature defined with “first” or “second” may explicitly or implicitly include one or more of the features. In the description of the embodiments of the present disclosure, the term “a/the plurality of” means two or more unless otherwise specified.

In the description of some embodiments, the term “connected” and derivatives thereof may be used. The term “connected” should be understood in a broad sense; for example, the term “connected” may represent a fixed connection, a detachable connection, or a one-piece connection; alternatively, it may represent a direct connection, or an indirect connection through an intermediate medium.

The phrase “at least one of A, B, and C” has the same meaning as the phrase “at least one of A, B, or C”, both including the following combinations of A, B, and C: only A, only B, only C, a combination of A and B, a combination of A and C, a combination of B and C, and a combination of A, B, and C.

The phrase “A and/or B” includes following three combinations: only A, only B, and a combination of A and B.

The phrase “applicable to” or “configured to” used herein is meant to be an open and inclusive expression, which does not exclude devices that are applicable to or configured to perform additional tasks or steps.

As used herein, the term “substantially” includes a stated value and an average value within an acceptable range of deviation of a particular value; the acceptable range of deviation may be determined, for example, by a person of ordinary skill in the art, considering measurement in question and errors (i.e., limitations of a measurement system) associated with measurement of a particular quantity.

As used herein, the term such as “parallel”, “perpendicular”, or “equal” includes a stated condition and a condition similar to the stated condition within an acceptable range of deviation; the acceptable range of deviation may be determined, for example, by a person of ordinary skill in the art, considering measurement in question and errors (i.e., limitations of a measurement system) associated with measurement of a particular quantity. For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, in a case where a layer or element is referred to as being on another layer or substrate, it may be that the layer or element is directly on the another layer or substrate, or it may be that intermediate layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

The directional terms such as “up”, “down”, “left”, and “right” described in the embodiments herein are described based on orientations shown in the accompanying drawings, and should not be construed as limitations on the embodiments of the present disclosure.

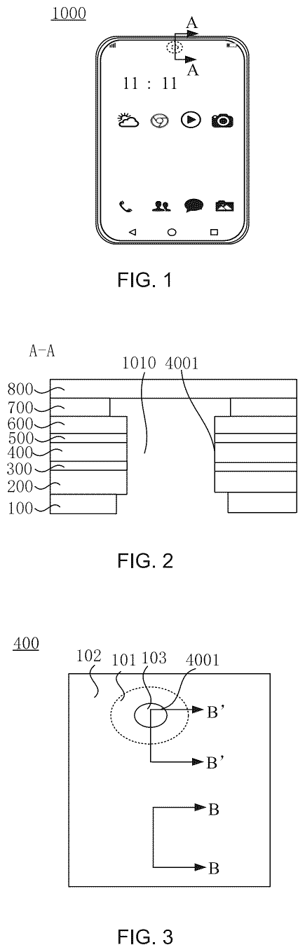

Some embodiments of the present disclosure provide a display apparatus, and as shown in FIG. 1, the display apparatus 1000 may be any apparatus that displays images whether in motion (e.g., a video) or stationary (e.g., static images) and whether textual or graphical. More specifically, it is expected that the display apparatus of the embodiments may be implemented in or associated with a variety of electronic devices, and the variety of electronic devices may include (but are not limit to), for example, mobile telephones, wireless devices, personal data assistants (PDAs), hand-held or portable computers, GPS receivers/navigators, cameras, MP4 video players, video cameras, game consoles, watches, clocks, calculators, TV monitors, flat panel displays, computer monitors, car displays (e.g., odometer displays), navigators, cockpit controllers and/or displays, camera view displays (e.g., rear view camera displays in vehicles), electronic photos, electronic billboards or indicators, projectors, building structures, packagings and aesthetic structures (e.g., a display for an image of a piece of jewelry), etc.

The display apparatus 1000 may be an organic light-emitting diode (OLED) display apparatus, a quantum dot light-emitting diode (QLED) display apparatus, or an active matrix organic light-emitting diode (AMOLED) display apparatus. Embodiments of the present disclosure are described with an example in which the display apparatus is an AMOLED display apparatus.

As shown in FIG. 2, the display apparatus 1000 includes a support layer 100, a back film 200, a first pressure-sensitive conductive adhesive 300, a display panel 400, a second pressure-sensitive conductive adhesive 500, a circular polarizer 600, a photosensitive adhesive 700, and a cover plate 800 that are sequentially stacked. The support layer 100 is used to support the display panel 400, a material of the support layer 100 may include stainless steel or aluminum, which will not be enumerated in the embodiments of the present disclosure. The back film 200 is used to reduce the risk of water and oxygen entering the display panel 400. The first pressure-sensitive conductive adhesive 300 is used to bond the display panel 400 and the back film 200, and the first pressure-sensitive conductive adhesive 300 covers the back film 200. The second pressure-sensitive conductive adhesive 500 is used to bond the display panel 400 and the circular polarizer 600, and the second pressure-sensitive conductive adhesive 500 covers the display panel 400. The circular polarizer 600 is used to reduce the reflection of ambient light by the display panel 400. The photosensitive adhesive 700 is used to bond the circular polarizer 600 and the cover plate 800. The cover plate 800 is located on a light exit side of the display panel 400. The cover plate 800 is used to protect the display panel 400.

As shown in FIG. 2, the display apparatus 1000 is provided with a first hole 1010 therein, and the first hole 1010 may be used to place a functional device. For example, the functional device is a device that may achieve a specific function, such as a front camera assembly, a fingerprint assembly, a 3D face recognition assembly, an iris recognition assembly or a proximity sensor. The embodiments of the present disclosure are described by taking an example in which the functional device is a front camera assembly.

As shown in FIG. 2, the first hole 1010 penetrates the support layer 100, the back film 200, the first pressure-sensitive conductive adhesive 300, the display panel 400, the second pressure-sensitive conductive adhesive 500, the circular polarizer 600 and the photosensitive adhesive 700; there is only the cover plate 800 on an upper side of the front camera assembly, and the cover plate 800 has a high transmittance (e.g., the transmittance is greater than 85%), so that the front camera assembly receives sufficient light, which may ensure a good imaging quality of the front camera assembly. The cover plate 800 may reduce the risk of collision between the front camera and other objects to reduce the risk of the front camera being damaged.

A shape of an orthographic projection of the first hole 1010 on the cover plate 800 may be determined according to actual needs. For example, the orthographic projection of the first hole 1010 on the cover plate 800 may be in a shape of a circle, a polygon, a sector, or an irregular figure, which will not be enumerated in the embodiments of the present disclosure. In embodiments of the present disclosure, description is made with an example in which the orthographic projection of the first hole 1010 on the cover plate 800 is in a shape of a circle.

In some embodiments, as shown in FIGS. 2 and 3, the first hole 1010 penetrates the display panel 400 to form a through hole 4001. The display panel 400 has an isolation region 101, a through hole region 103 and a display region 102. The isolation region 101 surrounds the through hole region 103, a portion of the display panel 400 located in the through hole region 103 includes the through hole 4001, and the display region 102 surrounds the isolation region 101.

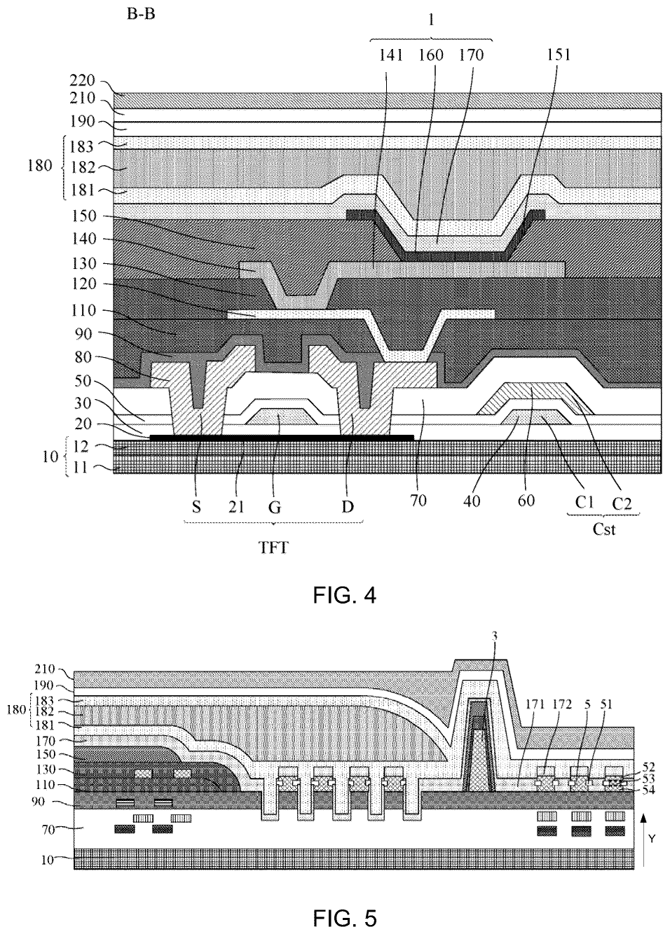

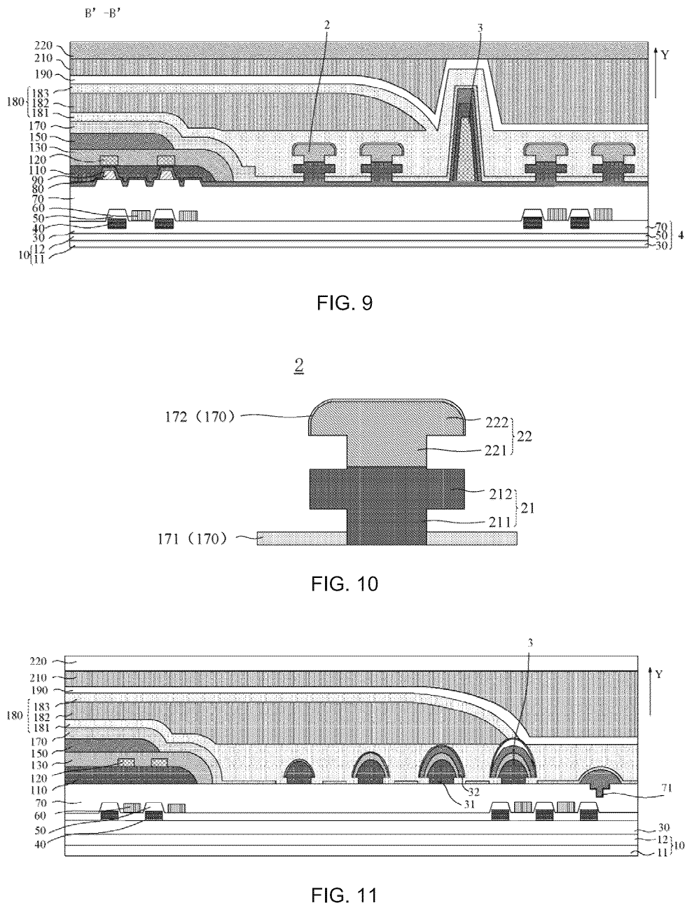

FIG. 4 is a sectional view of the display panel in FIG. 3 taken along the section line B-B. FIG. 9 is a sectional view of the display panel in FIG. 3 taken along the section line B′-B′. As shown in FIGS. 3, 4 and 9, in the display region 102, the display panel 400 includes a substrate 10, and an active layer 20, a first gate insulating layer 30, a first gate metal layer 40, a second gate insulating layer 50, a second gate metal layer 60, an interlayer dielectric layer 70, a first source-drain metal layer 80, a passivation layer 90, a first planarization layer 110, a second source-drain metal layer 120, a second planarization layer 130, an anode layer 140, a pixel defining layer 150, a light-emitting functional layer 160, a cathode layer 170, and an encapsulation layer 180 that are arranged in a direction away from the substrate 10.

In some embodiments, as shown in FIG. 4, the substrate 10 may be a flexible substrate 10 or a rigid substrate 10; a material of the rigid substrate 10 may be glass, and a material of the flexible substrate 10 may be polyimide (PI). The substrate 10 may be of a single-layer structure or a multi-layer structure. For example, in a case where the substrate 10 is of a multi-layer structure, the substrate 10 may include a base 11 and a buffer layer 12 disposed on the base 11. A material of the buffer layer 12 may include silicon oxide, silicon nitride, or laminated silicon oxide and silicon nitride, which is not specifically limited in the embodiments of the present disclosure.

The active layer 20 is located on the substrate 10, and the active layer 20 includes a plurality of active patterns 21. A material of the active layer 20 may include polysilicon or an oxide material, which will not be enumerated in the embodiments of the present disclosure. For example, the material of the active layer 20 includes an oxide material.

The first gate insulating layer 30 is located on a side of the active layer 20 away from the substrate 10. A material of the first gate insulating layer 30 may be silicon oxide, silicon nitride or silicon oxynitride, which will not be enumerated in the embodiments of the present disclosure.

The first gate metal layer 40 is located on a side of the first gate insulating layer 30 away from the substrate 10, and the first gate metal layer 40 includes a plurality of gates G and a plurality of first plates C1. A material of the first gate metal layer 40 may include a material with excellent electrical conductivity such as aluminum (Al), silver (Ag), copper (Cu), or chromium (Cr).

The second gate insulating layer 50 is located on a side of the first gate metal layer 40 away from the substrate 10, and a material of the second gate insulating layer 50 may be the same as the material of the first gate insulating layer 30.

The second gate metal layer 60 is located on a side of the second gate insulating layer 50 away from the substrate 10, and the second gate metal layer 60 includes a plurality of second plates C2. A material of the second gate metal layer 60 may be the same as the material of the first gate metal layer 40. A first plate C1 and a second plate C2 constitute a capacitor Cst.

The interlayer dielectric layer 70 is located on a side of the second gate metal layer 60 away from the substrate 10. A material of the interlayer dielectric layer 70 includes silicon oxide, silicon nitride, silicon oxynitride, aluminum oxide or titanium oxide, which will not be enumerated in the embodiments of the present disclosure.

The first source-drain metal layer 80 is located on a side of the interlayer dielectric layer 70 away from the substrate 10, and the first source-drain metal layer 80 includes a plurality of sources S and a plurality of drains D. A material of the first source-drain metal layer 80 may be the same as the material of the first gate metal layer 40. An active pattern 21, a source S, a drain D and a gate G constitute a thin film transistor (TFT).

The passivation layer 90 is located on a side of the first source-drain metal layer 80 away from the substrate 10. The passivation layer 90 may reduce the risk of moisture and foreign matter in the air entering the first source-drain metal layer 80 to reduce the risk of damage to the first source-drain metal layer 80. A material of the passivation layer 90 may be the same as the material of the first gate insulating layer 30.

The first planarization layer 110 is located on a side of the passivation layer 90 away from the substrate 10. The first planarization layer 110 is used to planarize a surface of the passivation layer 90 away from the substrate 10, which may reduce the risk of unevenness of the anode layer 140 formed in a subsequent process due to an uneven surface of the passivation layer 90 away from the substrate 10. A material of the first planarization layer 110 may include an organic insulating material. The first planarization layer 110 is made of an organic insulating material; for example, the organic insulating material includes resin materials such as polyimide, epoxy resin, acrylic, polyester, photoresist, polyacrylate, polyamide, or siloxane; for another example, the organic insulating material includes an elastic material, and the elastic material includes urethane, thermoplastic polyurethane, or the like.

The second source-drain metal layer 120 is located on a side of the first planarization layer 110 away from the substrate 10 and is used to connect the first source-drain metal layer 80 to the anode layer 140. A material of the second source-drain metal layer 120 may be the same as the material of the first source-drain metal layer 80.

The second planarization layer 130 is located on a side of the second source-drain metal layer 120 away from the substrate 10 and is used to planarize a surface of the second source-drain metal layer 120 away from the substrate 10. A material of the second planarization layer 130 may be the same as the material of the first planarization layer 110.

The anode layer 140 is located on a side of the second planarization layer 130 away from the substrate 10, and the anode layer 140 includes a plurality of anodes 141. A material of the anode layer 140 may include indium tin oxide (ITO).

The pixel defining layer 150 is located on a side of the anode layer 140 away from the substrate 10, and the pixel defining layer 150 is provided with a plurality of openings 151 therein. A material of the pixel defining layer 150 may be the same as the material of the second planarization layer 130.

The light-emitting functional layer 160 is located on a side of the anode layer 140 away from the substrate 10 and partially located in the opening, and is connected to the anode layer 140.

The cathode layer 170 is disposed on a side of the pixel defining layer 150 away from the substrate 10 and is of a continuous whole-layer structure. Portions of an anode 141, the light-emitting functional layer 160, and the cathode layer 170 whose orthographic projections on the substrate 10 overlap may constitute a light-emitting device; the anode and the cathode layer 170 respectively inject holes and electrons into the light-emitting functional layer 160, the holes and electrons combine to form excitons, and light is emitted in response to the excitons transitioning from an excited state to a ground state.

The encapsulation layer 180 is located on a side of the cathode layer 170 away from the substrate 10 and located in the display region 102 and the isolation region 101. The encapsulation layer 180 may be an encapsulation film. The number of layers of encapsulation films included in the encapsulation layer 180 is not limited in the embodiments of the present disclosure. In some embodiments, the encapsulation layer 180 may include one layer of encapsulation film, or two or more layers of encapsulation films that are stacked. For examples, the encapsulation layer 180 includes a first inorganic encapsulation layer 181, a first organic encapsulation layer 182 and a second inorganic encapsulation layer 183 that stacked in a direction perpendicular to the substrate 10 and away from the substrate 10; the first organic encapsulation layer 182 is located between the first inorganic encapsulation layer 181 and the second inorganic encapsulation layer 183. Materials of the first inorganic encapsulation layer 181 and the second inorganic encapsulation layer 183 include any one of silicon nitride, silicon oxynitride or silicon oxide, or a combination thereof. A material of the first organic encapsulation layer 182 includes polymer resin, such as polyimide.

In some embodiments, as shown in FIGS. 4 and 9, the display panel 400 further includes a touch insulating layer 190, a second organic encapsulation layer 210 and a touch protection layer 220. The touch insulating layer 190 is located on a side of the second inorganic encapsulation layer 183 away from the substrate 10, the second organic encapsulation layer 210 is located on a side of the touch insulating layer 190 away from the substrate 10, and the touch protection layer 220 is located on a side of the second organic encapsulation layer 210 away from the substrate 10.

In the related art, a display panel 400 includes a through hole 4001 in a through hole region 103, so that in an encapsulation process of the display panel 400, defects such as crack, scratching or pinching will occur in the display panel 400 due to an action of external pressure, which will cause moisture to enter a portion of the display panel 400 located in the through hole region 103 to damage the display panel 400. That is, a growing dark spot in hole (GDSH) phenomenon easily occurs in a display panel provided with the through hole 4001. A cathode layer 170 is of a continuous whole-layer structure, so that the moisture may enter a portion of the display panel located in a display region 102 through the cathode layer 170. As a result, the display effect of the display panel is reduced.

In order to alleviate the above phenomenon, the display panel 400 generally includes an isolation structure 5. As shown in FIGS. 4 and 5, the isolation structure 5 is located on a side of the passivation layer 90 away from the first gate metal layer 40. The isolation structure 5 can divide the cathode layer 170 into a first portion 171 and a second portion 172. It will be understood that, the isolation structure 5 has a certain height, so that in a process of forming the cathode layer 170 by evaporation, the cathode layer 170 is automatically broken off at the isolation structure 5 and forms the first portion 171 and the second portion 172, and the first portion 171 is lower than the second portion 172. The first portion 171 is located between the passivation layer 90 and the encapsulation layer 180 and is in contact with a sidewall of the isolation structure 5; the second portion 172 is located on a side of the isolation structure 5 away from the passivation layer 90. The isolation structure 5 divides the cathode layer 170 into two portions, so that cathode layers 170 on two sides of the isolation structure 5 are insulated from each other to avoid a connection between electrodes, which may reduce the risk of moisture entering the display region 102 from the through hole region 103 through the cathode layer 170 to prolong the service life of the display panel 400.

However, in a test phase of the display panel 400, the through hole 4001 of the display panel 400 needs to be tested. For example, in a push on hole edge (POHE) test, a certain pressure needs to be applied to the through hole 4001. It will be understood that, the cathode layer 170 is a powdery substance in essence, and an adhesion between the encapsulation layer 180 and the cathode layer 170 is small in a case where the encapsulation layer 180 is in direct contact with the cathode layer 170. As shown in FIG. 7, as the pressure increases, a peeling phenomenon may occur between the cathode layer 170 and the encapsulation layer 180 in the isolation region 101 due to insufficient adhesion between the film layers, and the peeling in the isolation region 101 will extend from the isolation structure 5 to a portion of the display panel located in the display region 102. As a result, the display effect is affected.

In addition to the peeling phenomenon between the film layers of the display panel 400, there is another reason that leads to the product failure. In the related art, the isolation structure 5 is made of a metal material, such as aluminum. The metal material is overetched to form a recess 51 in the isolation structure 5, and the recess 51 is then used to break the cathode layer 170 off, thereby blocking the intrusion of water and oxygen. However, in the test process, a conductive adhesive material of the second pressure-sensitive conductive adhesive 500 (as shown in FIG. 2) will extend vertically downward to be connected to the cathode layer 170 along a cutting path. In this case, since the conductive adhesive material contains conductive ions, the cathode layer 170 is charged. The cathode layer 170 may easily enter the recess 51 of the isolation structure 5 in a deposition process, so that the cathode layer 170 in the entire isolation region 101 is negatively charged in a case where the display region 102 is energized. Due to an action of electrodes and moisture, chemical substances in the conductive adhesive react with the encapsulation layer 180, which causes the encapsulation layer 180 to be corroded and swell to form voids, and thus the moisture may easily enter the voids and lead to an encapsulation failure and then the product failure.

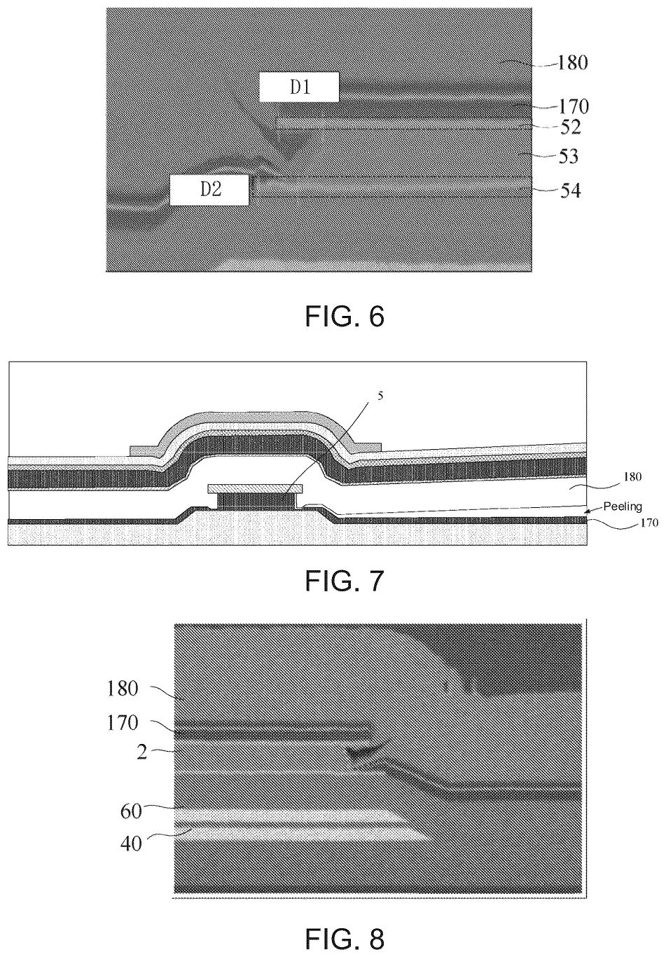

As shown in FIGS. 5 and 6, in some examples, the isolation structure 5 includes a first isolation layer 52, a second isolation layer 53, and a third isolation layer 54 that are stacked in a first direction Y. The first isolation layer 52 has a first portion extending outside, and the third isolation layer has a second portion extending outside. The first portion has a first width D1, and the second portion has a second width D2. The first portion extending outside and the second portion extending outside define the recess 51, and a portion of the encapsulation layer 180 enters into the recess.

FIG. 8 is an electron microscope picture of a display panel, in accordance with some embodiments. As shown in FIG. 8, it has been found through researches that, a portion of the encapsulation layer 180 extends into the isolation structure 5; in the case where the encapsulation layer 180 is in direct contact with the cathode layer 170, the adhesion between the two film layers is relatively small, but an adhesion at a region where the encapsulation layer 180 and the isolation structure 5 are in contact with each other is relatively large.

In view of this, some embodiments of the present disclosure provide a display panel 400.

In some embodiments, the first direction Y is perpendicular to the substrate 10 (i.e., perpendicular to a plane where the substrate 10 is located). For convenience of description, the following description is made by taking an example in which the first direction is a direction Y. As shown in FIGS. 9 and 10, the display panel further includes isolation pillar(s) 2. The isolation pillar(s) 2 are located on the substrate 10 and located in the isolation region 101, and are each arranged to surround the through hole region 103. The isolation pillar 2 includes a first isolation pillar 21 and a second isolation pillar 22 that are stacked in the first direction Y, and the first isolation pillar 21 is located between the substrate 10 and the second isolation pillar 22.

The first isolation pillar 21 includes a first pillar body 211 and a first extension layer 212 that are stacked in first direction Y; the first pillar body 211 is located between the first extension layer 212 and the substrate 10, an orthographic projection of the first pillar body 211 on the substrate 10 is located in an orthographic projection of the first extension layer 212 on the substrate 10, and the first pillar body 211 and the first extension layer 212 are disposed in the same layer. The phase “being disposed in the same layer” here and hereinafter refers to being disposed in a layer structure formed through a single patterning process by using a same mask in which a film layer for forming a specific pattern is formed by using a same film-forming process. Depending on different specific patterns, the single patterning process may include multiple times of exposure, development, or etching, and the specific pattern formed in the layer structure may be continuous or discontinuous, and these specific patterns may also be at different heights or have different thicknesses. In this way, sections of the first pillar body 211 and the first extension layer 212 constitute a “T-shaped structure”. In a case where the first isolation pillar 21 is not bonded to other film layers, except the first pillar body 211 of the first isolation pillar 21, a region below the first extension layer 212 is empty.

The second isolation pillar 22 includes a second pillar body 221 and a second extension layer 222 that are stacked in the first direction Y; the second pillar body 221 is located between the second extension layer 222 and the first isolation pillar 21, an orthographic projection of the second pillar body 221 on the substrate 10 is located in an orthographic projection of the second extension layer 222 on the substrate 10, and the second pillar body 221 and the second extension layer 222 are disposed in the same layer. In this way, sections of the second pillar body 221 and the second extension layer 222 constitute a “T-shaped structure”. In a case where the second isolation pillar 22 is not bonded to other film layers, except the first isolation pillar 21 and the second pillar body 221 of the second isolation pillar 22, a region below the second extension layer 222 is empty.

As shown in FIGS. 9 and 10, a portion of the encapsulation layer 180 extends between the first extension layer 212 and the cathode layer 170, and another portion of the encapsulation layer 180 extends between the second extension layer 222 and the first isolation pillar 21.

The encapsulation layer 180 is connected to the first pillar body 211, which may be understood as a connection between an organic matter and an organic colloid; an adhesion between the encapsulation layer 180 and the first pillar body 211 is much greater than the adhesion between the encapsulation layer 180 and the cathode layer 170 that are directly connected.

An encapsulation layer 180 and a cathode layer 170 of a display panel 400 in some examples are generally in direct contact with each other, and an adhesion between the two film layers is relatively small, so that a peeling phenomenon (as shown in FIG. 7) easily occurs between the two film layers. However, in the embodiments of the present disclosure, the second isolation pillar 22 is provided, a portion of the encapsulation layer 180 extends between the first extension layer 212 and the cathode layer 170, and another portion of the encapsulation layer 180 extends between the second extension layer 222 and the first isolation pillar 21. In this way, an area of direct contact between the encapsulation layer 180 and the isolation pillar 2 is increased, and the adhesion between the encapsulation layer 180 and the isolation pillar 2 is increased, which helps to avoid the peeling phenomenon between film layers to enhance the encapsulation effect of the encapsulation layer 180, thereby facilitating improving the product quality of the display panel 400.

In some embodiments, as shown in FIG. 9, the first planarization layer 110 is located between the substrate 10 and the cathode layer 170 and located in the display region 102 and the isolation region 101. The first planarization layer 110 and the first isolation pillar 21 are disposed in the same layer. In this way, the first planarization layer 110 and the first isolation pillar 21 may be formed through a single patterning process to reduce the number of times of patterning processes, which may save the manufacturing cost and improve the manufacturing efficiency.

In some embodiments, as shown in FIG. 9, the second planarization layer 130 is located between the first planarization layer 110 and the cathode layer 170 and located in the display region 102 and the isolation region 101. The second planarization layer 130 and the second isolation pillar 22 are disposed in the same layer. In this way, the second planarization layer 130 and the second isolation pillar 22 may be formed through a single patterning process to reduce the number of times of patterning processes, which may save the manufacturing cost and improve the manufacturing efficiency.

It can be seen from the above embodiments that, the first isolation pillar 21 and the second isolation pillar 22 are both made of organic materials; in testing the product, the conductive adhesive material extend vertically downward to be connected to the cathode layer 170 along the cutting path, the conductive adhesive material contains conductive ions, so that the cathode layer 170 is charged; in this case, since the organic material is not electrical conductive, even the cathode layer 170 enters an void of the isolation pillar 2 in the deposition process, the isolation pillar 2 may still prevent the cathode layer 170 from being connected to avoid the chemical substances in the conductive adhesive from reacting with the encapsulation layer 180, which helps to protect the display panel 400.

In some embodiments, as shown in FIG. 9, the pixel defining layer 150 and the second planarization layer 130 are disposed in the same layer. In addition, it is mentioned above that the material of the pixel defining layer 150 may be the same as the material of the second planarization layer 130. It will be understood that, the second planarization layer 130 may be replaced by the pixel defining layer 150, and the pixel defining layer 150 may be formed on the first planarization layer 110 after the first planarization layer 110 is formed, thereby saving the manufacturing cost and improving the manufacturing efficiency.

In some embodiments, as shown in FIG. 9, there are a plurality of isolation pillars 2, and the plurality of isolation pillars 2 are arranged at intervals in a direction perpendicular to a border of the through hole region 103. In this way, the cathode layer 170 is broken off at at least one isolation pillar 2 to cause the cathode layer 170 located in the isolation region 101 to be disconnected, which may reduce the risk of failure of the encapsulation layer 180.

In some embodiments, referring to FIG. 9, the display panel 400 further includes a dam structure 3. The dam structure 3 is located in the isolation region 101 and is arranged surrounding the through hole 4001. It will be understood that, the dam structure 3 is configured to block water and oxygen to improve the water-oxygen blocking performance of the encapsulation layer 180. In the process of forming the first organic encapsulation layer 182, the dam structure 3 is also used to block the ink, so that the first organic encapsulation layer 182 is located on a side of the dam structure 3 away from the through hole 4001; thus, the second inorganic encapsulation layer 183 may completely cover the first organic encapsulation layer 182 to alleviate the problem of failure of the first organic encapsulation layer 182 due to an intrusion of water and oxygen into the first organic encapsulation layer 182.

At least one isolation pillar 2 is located on a side of the dam structure 3 proximate to the through hole region 103, and another at least one isolation pillar 2 is located on a side of the dam structure 3 away from the through hole region 103. Due to the provision of the isolation pillar 2 located on the side of the dam structure 3 away from the through hole 4001, a surface of the first inorganic encapsulation layer 181 away from the substrate 10 is uneven, so that in the process of forming the first organic encapsulation layer 182, the uneven surface may reduce the flow rate of the ink to reduce the risk of the ink crossing over the dam structure 3.

In some embodiments, as shown in FIGS. 11, 12 and 13, a dam structure 3 is provided. The dam structure 3 may include a third pillar body 31 and a third extension layer 32 that are stacked in the first direction Y; the third pillar body 31 is located between the third extension layer 32 and the substrate 10, and an orthographic projection of the third pillar body 31 on the substrate 10 is located in an orthographic projection of the third extension layer 32 on the substrate 10. The second portion 172 of the cathode layer 170 is further located on a side of the third extension layer 32 away from the substrate 10.

In these embodiments, as shown in FIG. 11, the third pillar body 31 is located between the third extension layer 32 and the substrate 10; the third pillar body 31 may extend to the interlayer dielectric layer 70; a material of the third pillar body 31 may be an organic insulating material. With such design, it is possible to prevent cracks in the interlayer dielectric layer 70 from continuing extending to the display region 102. The third pillar body 31 and the first planarization layer 110 may be disposed in the same layer, so that the first planarization layer 110 and the third pillar body 31 may be formed through a single patterning process to reduce the number of times of patterning processes, which may save the manufacturing cost and improve the manufacturing efficiency.

In these embodiments, the third extension layer 32 is located on a side of the third pillar body 31 away from the substrate 10. It will be understood that, a highest portion of the third extension layer 32 in the first direction Y needs to block the first organic encapsulation layer 182 to block the ink, so that the first organic encapsulation layer 182 is located on the side of the dam structure 3 away from the through hole 4001. Thus, the second inorganic encapsulation layer 183 may completely cover the first organic encapsulation layer 182 to alleviate the problem of failure of the first organic encapsulation layer 182 due to the intrusion of water and oxygen into the first organic encapsulation layer 182.

In addition, the orthographic projection of the third pillar body 31 on the substrate 10 is located in the orthographic projection of the third extension layer 32 on the substrate 10; that is, in a case where the dam structure 3 is not bonded to other film layers, a region below the third extension layer 32 is empty except the third pillar body 31. With the above design, the cathode layer 170 may be broken off at the third pillar body 31, which may reduce the risk of current leakage from the display region 102 to the through hole 4001. It will be understood that, the dam structure 3 achieves the function as the isolation pillar 2 does. It will be understood that, the dam structure 3 is generally made of an organic material, and the organic material is not electrical conductive and does not have an electrical connection with the cathode layer 170. Therefore, due to the provision of the dam structure 3 in some embodiments of the present disclosure, it is possible to prevent the cathode layer 170 from connecting, which is conducive to protecting the display panel 400. In addition, the dam structure 3 is much higher than a conventional isolation pillar, which helps to prevent cracks from extending.

In the related art, the bezel of the display apparatus is developed continuously towards narrow bezel; the bezel in the related art is narrow, and the width of the bezel has been maintained above 200 μm, in which the design of the isolation region 101 mainly accounts for most of the region. At present, according to customer needs, the design of narrow bezel is the design trend of future display apparatuses.

It will be understood that, the dam structure 3 in the above embodiments achieves the function as the isolation pillar 2 does. Therefore, when manufacturing the display panel 400, it is possible to only form the dam structure 3 in the above embodiments to save the region occupied by the isolation pillar 2, which reduces the region occupied by the isolation region 101, thereby reducing the space occupied by the bezel and facilitating the realization of the narrow bezel design.

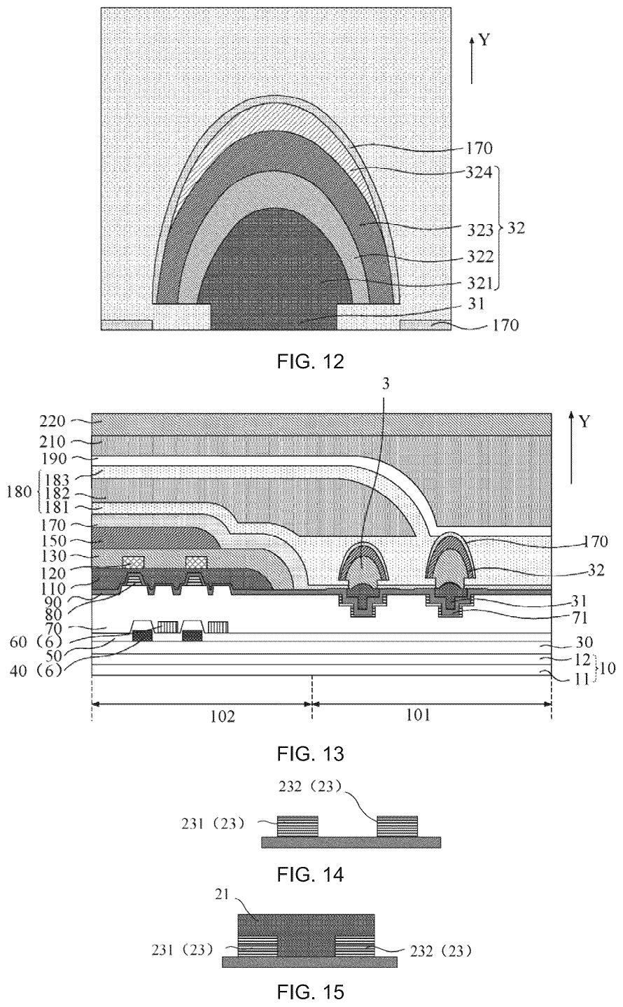

In some embodiments, as shown in FIGS. 11 and 12, a thickness of an edge portion of the third extension layer 32 is less than a thickness of a central portion of the third extension layer 32. That is, the third extension layer 32 is thick in the middle and thin at the edge. An edge of the first organic encapsulation layer 182 is located on the side of the dam structure 3 away from the through hole 4001, and a highest portion of the third extension layer 32 in the middle is higher than the edge of the first organic encapsulation layer 182. It will be understood that, the first organic encapsulation layer 182 descends rapidly in approaching the isolation region, and the middle portion of the dam structure 3 needs to be higher than the edge of the first organic encapsulation layer 182. As shown in FIGS. 12 and 13, the third extension layer of the dam structure 3 is high in the middle and gradually descends toward the edges on two sides, and then the formed dam structure 3 is in a shape of a “mushroom”. With the above design, the third extension layer 32 may block the ink during the process of forming the first organic encapsulation layer 182, so that the first organic encapsulation layer 182 is located on the side of the dam structure 3 away from the through hole 4001. Thus, the second inorganic encapsulation layer 183 may completely cover the first organic encapsulation layer 182 to alleviate the problem of failure of the first organic encapsulation layer 182 due to the intrusion of water and oxygen into the first organic encapsulation layer 182.

In some embodiments, as shown in FIG. 12, the third extension layer 32 includes a first sub-layer 321, a second sub-layer 322, a third sub-layer 323, and a fourth sub-layer 324 that are stacked in the first direction Y. The first sub-layer 321 is located between the second sub-layer 322 and the third pillar body 31, and the third sub-layer 323 is located between the second sub-layer 322 and the fourth sub-layer 324. The orthographic projection of the third pillar body 31 on the substrate 10 is located in an orthographic projection of the first sub-layer 321 on the substrate 10, the orthographic projection of the first sub-layer 321 on the substrate 10 is located in an orthographic projection of the second sub-layer 322 on the substrate 10, and the orthographic projection of the second sub-layer 322 on the substrate 10 is located in an orthographic projection of the third sub-layer 323 on the substrate 10. With the design in which the first sub-layer 321, the second sub-layer 322, the third sub-layer 323, and the fourth sub-layer 324 are stacked to have a certain height, it is conducive to block the ink during the process of forming the first organic encapsulation layer 182, so that the first organic encapsulation layer 182 is located on the side of the dam structure 3 away from the through hole 4001. Thus, the second inorganic encapsulation layer 183 may completely cover the first organic encapsulation layer 182 to alleviate the problem of failure of the first organic encapsulation layer 182 due to the intrusion of water and oxygen into the first organic encapsulation layer 182.

It will be understood that, the first sub-layer 321, the second sub-layer 322, the third sub-layer 323, and the fourth sub-layer 324 are all made to be thick in the middle and gradually thinner at the edge, so that the third extension layer formed after the first sub-layer 321, the second sub-layer 322, the third sub-layer 323, and the fourth sub-layer 324 are stacked is high in the middle and low at the edge, which helps to save the manufacturing cost.

In some embodiments, as shown in FIGS. 12 and 13, the first sub-layer 321, the second sub-layer 322, the third sub-layer 323, and the fourth sub-layer 324 may all made of organic materials. The third pillar body 31 may be disposed in the same layer as the first sub-layer 321 and the first planarization layer 110, so that the third pillar body 31, the first sub-layer 321 and the first planarization layer 110 may be formed through a single patterning process, which may reduce the number of times of patterning processes to save the manufacturing cost and improve the manufacturing efficiency.

The second sub-layer 322 and the second planarization layer 130 may be disposed in the same layer, so that the second sub-layer 322 and the second planarization layer 130 may be formed through a single patterning process, which may reduce the number of times of patterning processes to save the manufacturing cost and improve the manufacturing efficiency.

The third sub-layer 323 and the pixel defining layer 150 may be disposed in the same layer, so that the third sub-layer 323 and the pixel defining layer 150 may be formed through a single patterning process, which may reduce the number of times of patterning processes to save the manufacturing cost and improve the manufacturing efficiency.

The fourth sub-layer 324 and the touch insulating layer 190 may be disposed in the same layer, so that the fourth sub-layer 324 and the touch insulating layer 190 may be formed through a single patterning process, which may reduce the number of times of patterning processes to save the manufacturing cost and improve the manufacturing efficiency.

In these embodiments, the materials of the first planarization layer 110, the second planarization layer 130, the pixel defining layer 150 and the touch insulating layer 190 may all refer to the description of the above embodiments, which will not be repeated here.

In the related art, in the process of cutting the through hole 4001, the cutting stress will cause cutting cracks, and the cutting cracks will extend to the display region 102 along the interlayer dielectric layer 70, resulting in a decrease in the qualified rate of the display panel 400 and an increase in the manufacturing cost of the display panel 400.

In some embodiments, as shown in FIGS. 11 and 13, the interlayer dielectric layer 70 includes a blocking recess 71, the blocking recess 71 is located in the isolation region 101, the passivation layer 90 is partially located in the blocking recess 71, and a portion of the dam structure 3 proximate the substrate 10 is located in the blocking recess 71 and on a side of the passivation layer 90 away from the interlayer dielectric layer 70. It will be understood that, the interlayer dielectric layer 70 is generally made of an inorganic material, and the cutting cracks formed in a process of cutting the through hole 4001 easily extend inside the interlayer dielectric layer 70. In order to prevent the cutting cracks from extending in the interlayer dielectric layer 70, the blocking recess 71 is generally provided in the interlayer dielectric layer 70; in a case where a cutting crack appears in the interlayer dielectric layer 70, the cutting crack extends in the interlayer dielectric layer 70 and extends to the blocking recess 71; since the cutting crack cannot extend without a medium, in the case where the cutting crack extends to the blocking recess 71, the cutting crack cannot extend crossing the blocking recess 71 due to the fact that there is no inorganic material in the blocking recess 71. Therefore, the cutting crack is blocked by the blocking recess 71, which helps to prevent the crack from further spreading inside the interlayer dielectric layer 70, thereby facilitating protecting the display panel 400 to improve the qualified rate of the display panel 400.

In these embodiments, as shown in FIG. 13, the passivation layer 90 is located in the blocking recess 71, and the portion of the dam structure 3 proximate to the substrate 10 is also located in the blocking recess 71 and is located on the side of the passivation layer 90 away from the interlayer dielectric layer 70. The dam structure 3 and the passivation layer 90 may be made of organic materials, and the organic materials have the property of being able to absorb and disperse stress. Therefore, the dam structure 3 and the passivation layer 90 located in the blocking recess 71 may absorb the cutting stress to reduce the risk that the cutting cracks caused by the cutting stress extends to the display region 102. Furthermore, the blocking recess 71 is disposed below the dam structure 3, which may further reduce the isolation region 101 to reduce the space occupied by the bezel, thereby facilitating the realization of the narrow bezel design.

In some embodiments, as shown in FIG. 13, the first source-drain metal layer 80 is further partially located in the blocking recess 71. It will be understood that, the first source-drain metal layer 80 is made of a metal material, and the metal material itself has a certain hardness and strength and is not easily deformed. Thus, the first source-drain metal layer 80 may be arranged to be in contact with an inner wall of the blocking recess 71 and match the inner wall of the blocking recess 71, so that the blocking recess 71 is not easily deformed. Moreover, the metal material has the property of being able to absorb and disperse stress. Therefore, the first source-drain metal layer 80 located in the blocking recess 71 may absorb the cutting stress to reduce the risk of the cutting cracks caused by the cutting stress extending to the display region 102.

In some embodiments, as shown in FIG. 13, a gate metal layer 6 includes the first gate metal layer and the second gate metal layer in the aforementioned embodiments and is partially located in the blocking recess 71. It will be understood that, the gate metal layer 6 is made of a metal material, and the metal material itself has a certain hardness and strength and is not easily deformed. Thus, the gate metal layer 6 may be arranged to be in contact with the inner wall of the blocking recess 71 and match the inner wall of the blocking recess 71, so that the blocking recess 71 is not easily deformed. Moreover, the metal material has the property of being able to absorb and disperse stress. Therefore, the gate metal layer 6 located in the blocking recess 71 may absorb the cutting stress to reduce the risk of the cutting cracks caused by the cutting stress extending to the display region 102.

In some embodiments, as shown in FIGS. 11 and 13, there are at least two dam structures 3; an orthographic projection of one of the at least two dam structures 3 on the substrate 10 is located in an orthographic projection of the first organic encapsulation layer 182 on the substrate 10, and another of the at least two dam structures 3 abuts an edge of the first organic encapsulation layer 182 located in the isolation region 101.

It will be understood that, the dam structure, whose orthographic projection on the substrate 10 is located in the orthographic projection of the first organic encapsulation layer 182 on the substrate 10, may protect the display region 102 to prevent the intrusion of water and oxygen; the dam structure abutting the edge of the first organic encapsulation layer 182 located in the isolation region 101 may prevent the ink of the first organic encapsulation layer 182 from overflowing, which helps to protect the encapsulation effect of the encapsulation layer 180.

Embodiments of the present disclosure provide a manufacturing method for a display panel 400; the display panel 400 includes a display region 102, a through hole region 103 and an isolation region 101; the through hole region 103 includes a through hole 4001; the isolation region 101 surrounds the through hole 4001, and the display region 102 is adjacent to the isolation region 101.

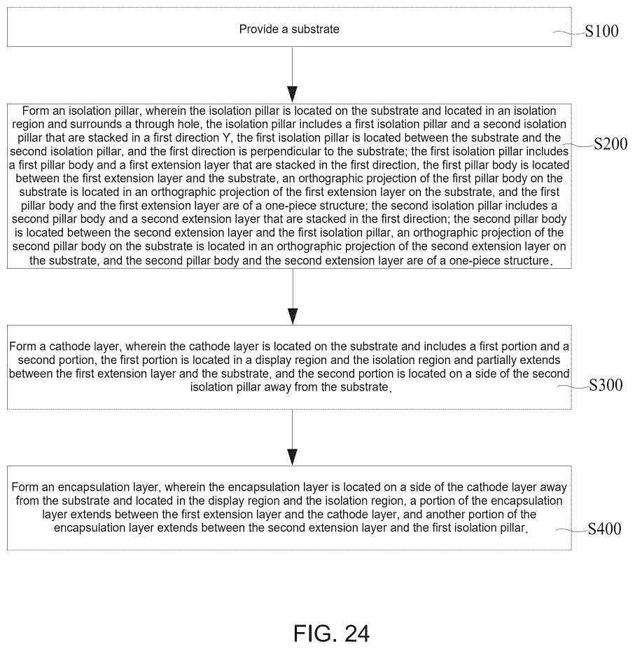

As shown in FIG. 24, the manufacturing method for the display panel 400 includes the following steps.

In the step S100, a substrate is provided. For example, the provided substrate may have a display region and an isolation region. The substrate may be a glass substrate or a flexible substrate. A material of the flexible substrate may include polyimide (PI); that is, the flexible substrate may be a PI substrate. For example, after preliminary processing, the display panel may include a flexible substrate, a buffer layer, a polycrystalline silicon layer, a first gate insulating layer, a first gate metal layer, a second gate insulating layer, a second gate metal layer, an interlayer dielectric layer, a first source-drain metal layer and a protective layer.

The substrate 10 may be made of polyimide (PI). Polyimide is a material with good temperature resistance among existing polymer materials and has excellent chemical durability and mechanical properties. Therefore, polyimide is considered to be a type of flexible substrate material with great potential.

The buffer layer 12 is generally made of an organic material by using a low-temperature film forming technique, because the film formed under a low temperature may extend a path of penetration of moisture, which prolongs the service life of the active matrix organic light-emitting diodes (AMOLEDs); another function of the buffer layer 12 is to planarize the surface of the substrate.

The polycrystalline silicon layer is made of a polycrystalline silicon material, which enables the display panel to have a high brightness and good color output without changing the backlight module.

The first gate insulating layer 30 may be a polyimide film layer; the polyimide film layer has a high bending strength and a high tensile strength; in a case where the base 11 is bent, the first gate insulating layer 30 may bend accordingly with the base 11 to ensure its insulation.

The first gate metal layer 40 is configured to create or eliminate a channel between a source and a drain, so as to allow electrons to flow through or block the electrons.

The second gate insulating layer 50 may be a polyimide film layer; the polyimide film layer has a high bending strength and a high tensile strength; in a case where the base 11 is bent, the second gate insulating layer 50 may bend accordingly with the base 11 to ensure its insulation.

The second gate metal layer 60 is configured to create or eliminate a channel between a source and a drain, so as to allow electrons to flow through or block the electrons.

The interlayer dielectric layer 70 is generally made of low-k dielectric to reduce time delay and increase speed.

The first source-drain metal layer 80 is configured to be connected to an active layer 20 through via holes in the interlayer dielectric layer 70 and the gate insulating layers.

The protective layer is an insulating layer referred to as a passivation layer 90 (PVX) on the substrate, which plays a role of protecting the substrate.

The buffer layer 12, the polycrystalline silicon layer, the first gate insulating layer 30, the first gate metal layer 40, the second gate insulating layer 50, the second gate metal layer 60, the interlayer dielectric layer 70, the first source-drain metal layer 80 and the protective layer may be formed through methods such as deposition, inkjet printing, and etching, and the specific processes may refer to existing technologies, which are not specifically limited in the present disclosure.

In the step S200, an isolation pillar is formed; the isolation pillar is located on the substrate and located in the isolation region and surrounds the through hole; the isolation pillar includes a first isolation pillar and a second isolation pillar that are stacked in a first direction; the first isolation pillar is located between the substrate and the second isolation pillar, and the first direction is perpendicular to the substrate.

The first isolation pillar includes a first pillar body and a first extension layer that are stacked in the first direction; the first pillar body is located between the first extension layer and the substrate; an orthographic projection of the first pillar body on the substrate is located in an orthographic projection of the first extension layer on the substrate, and the first pillar body and the first extension layer are of a one-piece structure.

The second isolation pillar includes a second pillar body and a second extension layer that are stacked in the first direction; the second pillar body is located between the second extension layer and the first isolation pillar; an orthographic projection of the second pillar body on the substrate is located in an orthographic projection of the second extension layer on the substrate, and the second pillar body and the second extension layer are of a one-piece structure.

For example, referring to FIG. 9, the isolation pillar 2 may be formed by a patterning process using a mask. The patterning process may include multiple exposure processes, development processes and etching processes. Etching belongs to a semiconductor manufacturing process and is a very important step in the microelectronics manufacturing process and the micro/nano manufacturing process. Etching is actually etching, in which an exposure process is first performed on photoresist by photolithography, and then portions that need to be removed are corroded and removed through other methods. With the development of micro manufacturing technology, etching, in a broad sense, is a general term for stripping and removing materials through solutions, reactive ions or other mechanical methods.

In the step S300, a cathode layer is formed; the cathode layer is located on the substrate; the cathode layer includes a first portion and a second portion; the first portion is located in the display region and the isolation region and partially extends between the first extension layer and the substrate; the second portion is located on a side of the second isolation pillar away from the substrate.

For example, the cathode layer 170 may include an electroluminescent film layer and a cathode film layer. The cathode layer 170 may be configured according to actual requirements for the display panel 400, and the specific method for forming the cathode layer 170 may refer to existing technologies, which is not specifically limited in the present disclosure.

In the electroluminescent film layer, an electroluminescent (EL) light source has the characteristics of low power consumption, soft light, no ultraviolet rays, various colors, long service life and no heat generation, and is generally known as a cold light source; different from the mechanism of conventional point or line luminescence, the EL light source achieves surface luminescence in a uniform and whole manner; furthermore, the EL light source is a light source that does not cause glare, and is harmless and flexible, and may be cut into any complex shape.

Since easy electron injection is a basic condition for selecting the material of the cathode film layer, a low-power material is selected as the material of the cathode film layer. With the cathode film layer made of a low-power material, not only the electron injection efficiency may be improved, but also the heat generated in an operation of the display panel may be reduced to prolong the service life of the display panel.

In the step S400, an encapsulation layer is formed; the encapsulation layer is located on a side of the cathode layer away from the substrate and located in the display region and the isolation region; a portion of the encapsulation layer extends between the first extension layer and the cathode layer, and another portion of the encapsulation layer extends between the second extension layer and the first isolation pillar.

For example, a first inorganic encapsulation layer 181, a first organic encapsulation layer 182 and a second inorganic encapsulation layer 183 are employed to form the encapsulation layer 180 to obtain a display substrate 10. For instance, the first inorganic encapsulation layer 181, the first organic encapsulation layer 182, and the second inorganic encapsulation layer 183 may be sequentially stacked to encapsulate the display panel 400. The first inorganic encapsulation layer 181, the first organic encapsulation layer 182, and the second inorganic encapsulation layer 183 are sequentially stacked, which includes sequentially stacking the first inorganic encapsulation layer 181, the first organic encapsulation layer 182 and the second inorganic encapsulation layer 183 on the substrate 10 located in a peripheral region and sequentially stacking the first inorganic encapsulation layer 181, the first organic encapsulation layer 182 and the second inorganic encapsulation layer 183 on the cathode layer 170 located in the display region 102. The first inorganic encapsulation layer 181, the first organic encapsulation layer 182 and the second inorganic encapsulation layer 183 may be formed through methods such as deposition, inject printing and etching, and the specific processes may refer to existing technologies, which are not specifically limited in the present disclosure.

The first inorganic encapsulation layer 181 and the second inorganic encapsulation layer 183 are used to encapsulate the display panel 400 to achieve an insulating effect. The first organic encapsulation layer 182 is patterned by using a non-contact patterning technology, in which ink droplets may be direct sprayed onto the substrate at designated positions to achieve patterning.

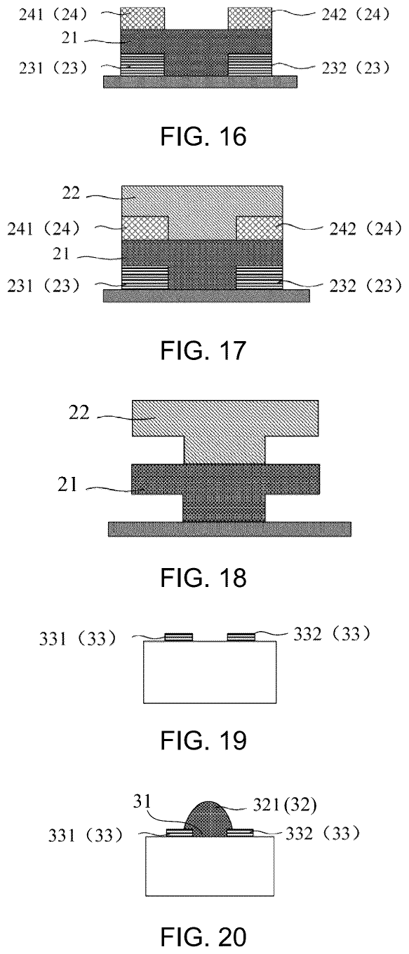

It will be understood that, the above-mentioned manufacturing method provided in the embodiments of the present disclosure is used to manufacture the display panel 400 provided in the embodiments of the present disclosure; since the isolation pillar 2 is manufactured as the stacked first isolation pillar 21 and second isolation pillar 22, a second sacrificial layer 24 is provided in the manufacturing process. Referring to FIGS. 16 to 18, after the second sacrificial layer 24 is etched, the space formed after a third sacrificial block 241 and a fourth sacrificial block 242 are removed by etching is filled with a portion of the encapsulation layer 180. It has been found through researches that, an adhesion between the encapsulation layer 180 and the isolation pillar 2 in a case where the encapsulation layer 180 is in direct contact with the isolation pillar 2 is stronger than an adhesion between the encapsulation layer 180 and the cathode layer 170 in a case where the encapsulation layer 180 is in direct contact with the cathode layer 170. Therefore, for the display panel 400 manufactured by using the above-mentioned manufacturing method provided in the embodiments of the present disclosure, an area of direct contact between the encapsulation layer 180 and the isolation pillar 2 is increased, so that the encapsulation effect of the encapsulation layer 180 is enhanced, which helps to prevent the peeling phenomenon between film layers to improve the product quality of the display panel 400.

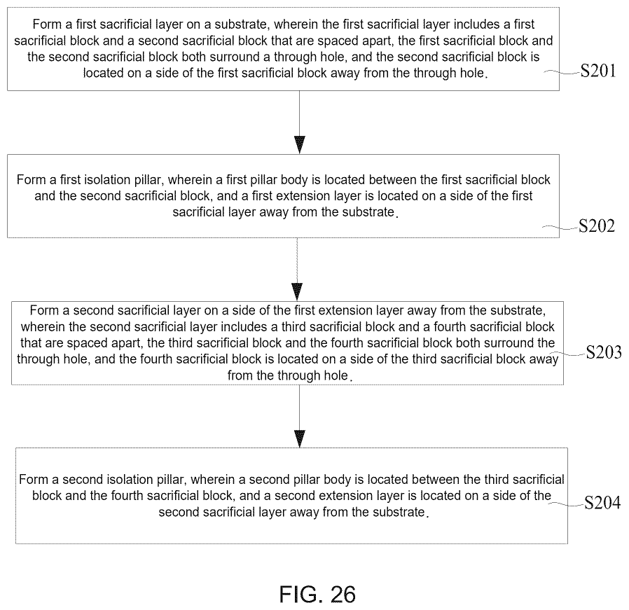

In some embodiments, as shown in FIG. 26, the step S200 in which the isolation pillar is formed may include the following steps.

In the step S201, a first sacrificial layer is formed on the substrate; the first sacrificial layer includes a first sacrificial block and a second sacrificial block that are spaced apart; the first sacrificial block and the second sacrificial block are both arranged surrounding the through hole, and the second sacrificial block is located on a side of the first sacrificial block away from the through hole.

For example, as shown in FIGS. 9 and 14, the first sacrificial block 231 and the second sacrificial block 232 are formed on the substrate 10 by deposition.

In the step S202, the first isolation pillar is formed; the first pillar body is located between the first sacrificial block and the second sacrificial block, and the second extension layer is located on a side of the first sacrificial layer away from the substrate.

For example, as shown in FIG. 15, the first isolation pillar 21 is formed on the first sacrificial layer 23 by deposition.

In the step S203, a second sacrificial layer is formed on a side of the first extension layer away from the substrate; the second sacrificial layer includes a third sacrificial block and a fourth sacrificial block that are spaced apart; the third sacrificial block and the fourth sacrificial block are both arranged surrounding the through hole, and the fourth sacrificial block is located on a side of the third sacrificial block away from the through hole.

For example, as shown in FIG. 16, the second sacrificial layer 24 is formed on the first isolation pillar 21 by deposition.

In the step S204, the second isolation pillar is formed; the second pillar body is located between the third sacrificial block and the fourth sacrificial block, and the second extension layer is located on a side of the second sacrificial layer away from the substrate.

For example, as shown in FIG. 17, the second isolation pillar 22 is formed on the second sacrificial layer 24 by deposition. Then, as shown in FIG. 18, the first sacrificial block 231, the second sacrificial block 232, the third sacrificial block 241, and the fourth sacrificial block 242 may all be removed by etching to form the isolation pillar.

In these embodiments, as an example, the first sacrificial block 231 and the second sacrificial block 232 may be disposed in the same layer as the first source-drain metal layer 80, and the third sacrificial block 241 and the fourth sacrificial block 242 may be disposed in the same layer as the second source-drain metal layer 120. The first sacrificial block 231 and the second sacrificial block 232 may have a certain height in the first direction Y, which is the height of the first pillar body 211; the third sacrificial block 241 and the fourth sacrificial block 242 may have a certain height in the first direction Y, which is the height of the second pillar body 221; with such a design, it is possible to help the breaking off for the cathode layer 170. After the first extension layer 212 is formed, the first sacrificial block 231, the second sacrificial block, the third sacrificial block 241, and the fourth sacrificial block 242 may all be removed by etching.

It will be understood that, as shown in FIGS. 9 and 10, the isolation pillar 2 manufactured by the manufacturing method provided in these embodiments has the first isolation pillar 21 and the second isolation pillar 22, which increases the area of direct contact between the encapsulation layer 180 and the isolation pillar 2 to increase the adhesion between the encapsulation layer 180 and the isolation pillar 2, thereby facilitating preventing the peeling phenomenon between film layers to enhance the encapsulation effect of the encapsulation layer 180. As a result, it is conducive to improve the product quality of the display panel 400. Furthermore, with the provision of the second isolation pillar 22, the height of the isolation pillar 2 is increased, which is more conducive to breaking the cathode layer 170 off and preventing the intrusion of water and oxygen. In addition, the isolation pillar 2 has a double-layer structure, which helps to increase the strength of the isolation pillar 2.

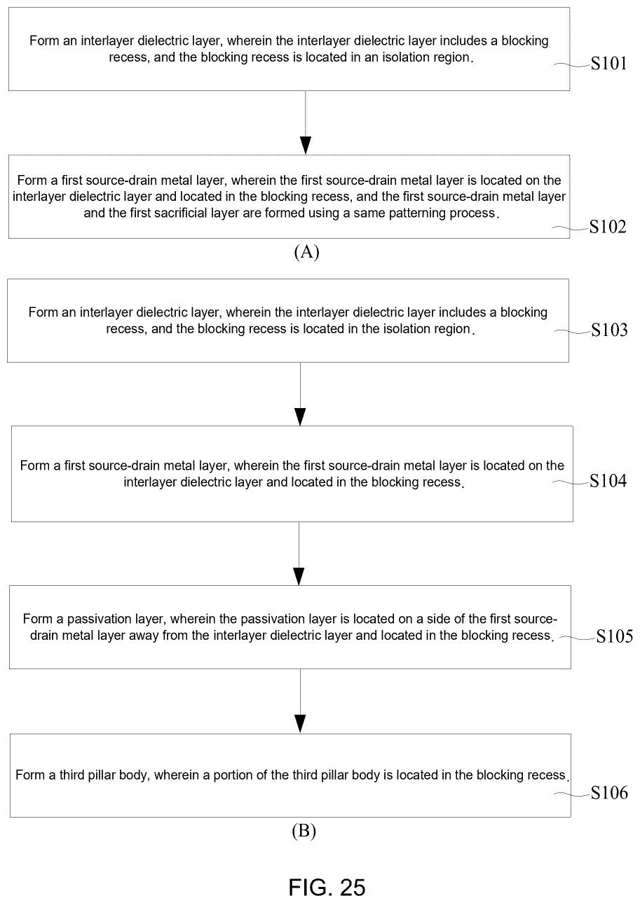

In some embodiments, as shown in (A) in FIG. 25, the manufacturing method further includes the following steps.

In the step S101, an interlayer dielectric layer is formed; the interlayer dielectric layer includes a blocking recess located in the isolation region.

In the step S102, a first source-drain metal layer is formed; the first source-drain metal layer is located on the interlayer dielectric layer and located in the blocking recess; the first source-drain metal layer and the first sacrificial layer are formed using a same patterning process.

It will be understood that, there is at least one blocking recess 71 between the display region 102 and the isolation region 101, and the blocking recess(s) 71 may be filled with an insulating material, so that the blocking recess 71 may effectively block the intrusion of moisture.

In some embodiments, after the step S100 in which the substrate 10 is provided, a dam structure 3 may be formed, which includes the following steps.

As shown in FIG. 19, a third sacrificial layer 33 is formed by deposition; the third sacrificial layer 33 is located on the substrate 10; the third sacrificial layer 33 includes a fifth sacrificial block 331 and a sixth sacrificial block 332 that are spaced apart; the fifth sacrificial block 331 and the sixth sacrificial block 332 are both arranged surrounding the through hole, and the sixth sacrificial block 332 is located on a side of the fifth sacrificial block 331 away from the through hole.

As shown in FIG. 20, a third pillar body 31 is formed; the third pillar body 31 is located between the fifth sacrificial block 331 and the sixth sacrificial block 332.

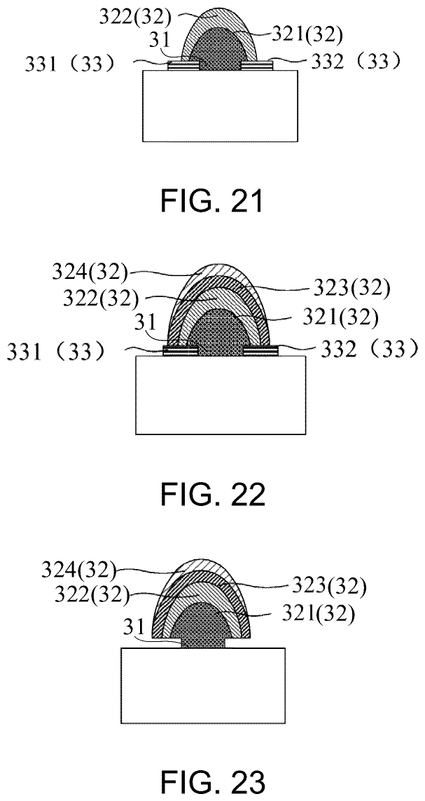

As shown in FIGS. 20 to 22, a third extension layer 32 is formed; the third extension layer 32 is located on a side of the third sacrificial layer 33 away from the substrate 10; an orthographic projection of the third pillar body 31 on the substrate 10 is located in an orthographic projection of the third extension layer 32 on the substrate 10; the third pillar body 31 and the third extension layer 32 constitute the dam structure 3.

For example, as shown in FIG. 20, a first sub-layer 321 is formed on the third pillar body 31 by deposition. As shown in FIG. 22, a third sub-layer 323 is formed on a second sub-layer 322 by deposition. A fourth sub-layer 324 is formed on the third sub-layer 323 by deposition. Then, as shown in FIG. 23, the fifth sacrificial block 331 and the sixth sacrificial block 332 of the third sacrificial layer 33 are removed by etching.

In the display panel 400, as shown in FIG. 9, the dam structure 3 is provided at a boundary of the peripheral region and the display region 102 of the substrate. In this way, not only an overflow of inkjet printing of the first organic encapsulation layer 182 may be blocked, but also the display region 102 and the through hole may be isolated from each other to block an intrusion of external moisture, thereby achieving a good encapsulation effect.

Therefore, the third pillar body 31 in these embodiments needs to be higher than the edge of the organic encapsulation layer in the first direction Y. After the third pillar body 31 and the third extension layer 32 are formed, the fifth sacrificial block 331 and the sixth sacrificial block 332 are removed by etching, which is conducive to breaking the cathode layer 170 off at this position to play the role of the isolation pillar. In this way, the isolation pillar may not be additionally formed, which helps to reduce the space occupied by the isolation region 101 and increase the area of the display region 102, thereby facilitating achieving the narrow bezel design of the display panel 400.

In some embodiments, as shown in (B) in FIG. 25, the manufacturing method for the display panel 400 further includes the following steps.

In the step S103, the interlayer dielectric layer is formed; the interlayer dielectric layer includes the blocking recess located in the isolation region.

In the step S104, the first source-drain metal layer is formed; the first source-drain metal layer is located on the interlayer dielectric layer and located in the blocking recess.

In the step S105, a passivation layer is formed; the passivation layer is located on a side of the first source-drain metal layer away from the interlayer dielectric layer and located in the blocking recess.

In the step S106, the third pillar body is formed; a portion of the third pillar body is located in the blocking recess.

It will be understood that, the manufacturing processes and functions of the interlayer dielectric layer 70, the first source-drain metal layer 80 and the passivation layer 90 may be the same as those mentioned in the above embodiments, which will not be repeated in these embodiments.

In these embodiments, as shown in FIGS. 3, 11, 12 and 13, a blocking recess 71 is formed before forming the dam structure 3; then, when forming the dam structure 3, the third pillar body 31 serving a portion of the dam structure 3 may be formed in the blocking recess 71. In this way, not only the blocking recess 71 may be filled to increase the strength of the blocking recess, but also the area of the isolation region 101 is reduced to increase the area of the display region 102, thereby facilitating achieving the narrow bezel design of the display panel 400.

In some embodiments, as shown in FIG. 13, before the step S300 in which the cathode layer 170 is formed, the manufacturing method may further include: forming a first planarization layer 110, a second source-drain metal layer 120 and a second planarization layer 130.

The first planarization layer, the second source-drain metal layer 120 and the second planarization layer may be formed through methods such as deposition, inject printing and etching, and the specific processes may refer to existing technologies, which are not specifically limited in the present disclosure.

For example, the second source-drain metal layer 120 may be disposed between the first planarization layer 110 and the second planarization layer 130.

The first planarization layer 110 and the second planarization layer 130 are both organic layers, which are used to meet the flatness requirement for the surface of the substrate.

The characteristics and advantages of the first planarization layer 110, the second source-drain metal layer 120 and the second planarization layer 130 provided in these embodiments have been described in the above embodiments and will not be repeated here. In the description of the specification, specific features, structures, materials, or characteristics may be combined in any one or more embodiments or examples in any suitable manner.

The above are merely specific embodiments of the present disclosure, but the protection scope of the present disclosure is not limited thereto, and variations or substitutions that any person skilled in the art may conceive of within the technical scope of the present disclosure should all fall within the protection scope of the present disclosure. Therefore, the protection scope of the present disclosure should be subjected to the protection scope of the claims.

What is claimed is:

1. A display panel comprising a display region, a through hole region and an isolation region, wherein the isolation region surrounds the through hole region, the display region is adjacent to the isolation region, and a portion of the display panel that is located in the through hole region includes a through hole; the display panel comprises:
a substrate;
an isolation pillar located on the substrate and located in the isolation region and surrounding the through hole region, wherein the isolation pillar includes a first isolation pillar and a second isolation pillar that are stacked in a first direction, the first isolation pillar is located between the substrate and the second isolation pillar, and the first direction is perpendicular to the substrate; wherein
the first isolation pillar includes a first pillar body and a first extension layer that are stacked in the first direction; the first pillar body is located between the first extension layer and the substrate, an orthographic projection of the first pillar body on the substrate is located in an orthographic projection of the first extension layer on the substrate, and the first pillar body and the first extension layer are of a one-piece structure; and
the second isolation pillar includes a second pillar body and a second extension layer that are stacked in the first direction; the second pillar body is located between the second extension layer and the first isolation pillar, an orthographic projection of the second pillar body on the substrate is located in an orthographic projection of the second extension layer on the substrate, and the second pillar body and the second extension layer are of a one-piece structure;
a cathode layer located on the substrate and including a first portion and a second portion, wherein the first portion is located in the display region and the isolation region and partially extends between the first extension layer and the substrate, and the second portion is located on a side of the second isolation pillar away from the substrate; and
an encapsulation layer located on a side of the cathode layer away from the substrate and located in the display region and the isolation region, wherein a portion of the encapsulation layer extends between the first extension layer and the cathode layer, and another portion of the encapsulation layer extends between the second extension layer and the first isolation pillar.

2. The display panel according to claim 1, further comprising:
a first planarization layer located between the substrate and the cathode layer and located in the display region and the isolation region, wherein the first planarization layer and the first isolation pillar are arranged in a same layer.

3. The display panel according to claim 2, further comprising:
a second planarization layer located between the first planarization layer and the cathode layer and located in the display region and the isolation region, wherein the second planarization layer and the second isolation pillar are arranged in a same layer.

4. The display panel according to claim 3, further comprising:
a pixel defining layer located between the first planarization layer and the cathode layer and located in the display region and the isolation region, wherein the pixel defining layer and the second planarization layer are arranged in a same layer.

5. The display panel according to claim 4, wherein
the display panel comprises a plurality of isolation pillars, and the plurality of isolation pillars are arranged at intervals in a direction perpendicular to a border of the through hole.

6. The display panel according to claim 5, further comprising:
a dam structure located in the isolation region and surrounding the through hole;
wherein at least one isolation pillar of the plurality of isolation pillars is located on a side of the dam structure proximate to the through hole, and another at least one isolation pillar of the plurality of isolation pillars is located on a side of the dam structure away from the through hole.

7. The display panel according to claim 6, wherein the dam structure includes a third pillar body and a third extension layer that are stacked in the first direction, the third pillar body is located between the third extension layer and the substrate, and an orthographic projection of the third pillar body on the substrate is located in an orthographic projection of the third extension layer on the substrate; the second portion is further located on a side of the third extension layer away from the substrate.

8. The display panel according to claim 7, wherein a thickness of an edge portion of the third extension layer is less than a thickness of a central portion of the third extension layer.

9. The display panel according to claim 7, wherein the third extension layer includes a first sub-layer, a second sub-layer, a third sub-layer, and a fourth sub-layer that are stacked in the first direction, wherein the first sub-layer is located between the second sub-layer and the third pillar body, and the third sub-layer is located between the second sub-layer and the fourth sub-layer;
the orthographic projection of the third pillar body on the substrate is located in an orthographic projection of the first sub-layer on the substrate, the orthographic projection of the first sub-layer on the substrate is located in an orthographic projection of the second sub-layer on the substrate, and the orthographic projection of the second sub-layer on the substrate is located in an orthographic projection of the third sub-layer on the substrate.

10. The display panel according to claim 9, wherein
the third pillar body, the first sub-layer, and the first planarization layer are arranged in a same layer;
the second sub-layer and the second planarization layer are arranged in a same layer; and
the third sub-layer and the pixel defining layer are arranged in a same layer; and
the display panel further comprises a touch insulating layer, the touch insulating layer is located on a side of the encapsulation layer away from the substrate, and the fourth sub-layer and the touch insulating layer are arranged in a same layer.

11. The display panel according to claim 6, wherein the display panel further comprises an interlayer dielectric layer and a passivation layer that are stacked in the first direction, wherein the passivation layer is located between the cathode layer and the interlayer dielectric layer; and
the interlayer dielectric layer includes a blocking recess, the blocking recess is located in the isolation region, the passivation layer is partially located in the blocking recess, and a portion of the dam structure proximate to the substrate is located in the blocking recess and located on a side of the passivation layer away from the interlayer dielectric layer.

12. The display panel according to claim 11, wherein the display panel further comprises:
a first source-drain metal layer, wherein the first source-drain metal layer is located between the passivation layer and the interlayer dielectric layer, and the first source-drain metal layer is partially located in the blocking recess.

13. The display panel according to claim 11, wherein the display panel further comprises:
a gate metal layer, wherein the gate metal layer is located on a side of the interlayer dielectric layer away from the cathode layer, and the gate metal layer is partially located in the blocking recess.

14. The display panel according to claim 10, wherein the encapsulation layer includes a first inorganic encapsulation layer, an organic encapsulation layer, and a second inorganic encapsulation layer that are stacked in the first direction, and the organic encapsulation layer is located between the first inorganic encapsulation layer and the second inorganic encapsulation layer;
the display panel comprises at least two dam structures, an orthographic projection of a dam structure of the at least two dam structures on the substrate is located in an orthographic projection of the organic encapsulation layer on the substrate, and another dam structure of the at least two dam structures abuts an edge of the organic encapsulation layer located in the isolation region.

15. A display apparatus, comprising:
the display panel according to claim 1, and
a cover plate located on a side of the isolation pillar of the display panel away from the substrate of the display panel.

16. A manufacturing method for a display panel, wherein the display panel includes a display region, a through hole region and an isolation region, the isolation region surrounds the through hole region, the display region is adjacent to the isolation region, and a portion of the display panel that is located in the through hole region includes a through hole; the manufacturing method for the display panel comprises:
providing a substrate;
forming an isolation pillar, wherein the isolation pillar is located on the substrate and located in the isolation region and surrounds the through hole, the isolation pillar includes a first isolation pillar and a second isolation pillar that are stacked in a first direction, the first isolation pillar is located between the substrate and the second isolation pillar, and the first direction is perpendicular to the substrate; the first isolation pillar includes a first pillar body and a first extension layer that are stacked in the first direction, the first pillar body is located between the first extension layer and the substrate, an orthographic projection of the first pillar body on the substrate is located in an orthographic projection of the first extension layer on the substrate, and the first pillar body and the first extension layer are of a one-piece structure; the second isolation pillar includes a second pillar body and a second extension layer that are stacked in the first direction; the second pillar body is located between the second extension layer and the first isolation pillar, an orthographic projection of the second pillar body on the substrate is located in an orthographic projection of the second extension layer on the substrate, and the second pillar body and the second extension layer are of a one-piece structure;
forming a cathode layer, wherein the cathode layer is located on the substrate and includes a first portion and a second portion, the first portion is located in the display region and the isolation region and partially extends between the first extension layer and the substrate, and the second portion is located on a side of the second isolation pillar away from the substrate; and
forming an encapsulation layer, wherein the encapsulation layer is located on a side of the cathode layer away from the substrate and located in the display region and the isolation region, a portion of the encapsulation layer extends between the first extension layer and the cathode layer, and another portion of the encapsulation layer extends between the second extension layer and the first isolation pillar.

17. The manufacturing method for the display panel according to claim 16, wherein forming the isolation pillar includes:
forming a first sacrificial layer on the substrate, wherein the first sacrificial layer includes a first sacrificial block and a second sacrificial block that are spaced apart, the first sacrificial block and the second sacrificial block are both arranged surrounding the through hole, and the second sacrificial block is located on a side of the first sacrificial block away from the through hole;
forming the first isolation pillar, wherein the first pillar body is located between the first sacrificial block and the second sacrificial block, and the first extension layer is located on a side of the first sacrificial layer away from the substrate;
forming a second sacrificial layer on a side of the first extension layer away from the substrate, wherein the second sacrificial layer includes a third sacrificial block and a fourth sacrificial block that are spaced apart, the third sacrificial block and the fourth sacrificial block are both arranged surrounding the through hole, and the fourth sacrificial block is located on a side of the third sacrificial block away from the through hole; and
forming the second isolation pillar, wherein the second pillar body is located between the third sacrificial block and the fourth sacrificial block, and the second extension layer is located on a side of the second sacrificial layer away from the substrate.

18. The manufacturing method for the display panel according to claim 17, wherein the manufacturing method for the display panel further comprises:
forming an interlayer dielectric layer, wherein the interlayer dielectric layer includes a blocking recess, and the blocking recess is located in the isolation region; and
forming a first source-drain metal layer, wherein the first source-drain metal layer is located on the interlayer dielectric layer and partially located in the blocking recess, and the first source-drain metal layer and the first sacrificial layer are formed using a same patterning process.

19. The manufacturing method for the display panel according to claim 16, wherein after providing the substrate, the manufacturing method for the display panel further comprises:
forming a third sacrificial layer on the substrate, wherein the third sacrificial layer includes a fifth sacrificial block and a sixth sacrificial block that are spaced apart, the fifth sacrificial block and the sixth sacrificial block are both arranged surrounding the through hole, and the sixth sacrificial block is located on a side of the fifth sacrificial block away from the through hole;
forming a third pillar body, wherein the third pillar body is located between the fifth sacrificial block and the sixth sacrificial block; and
forming a third extension layer, wherein the third extension layer is located on a side of the third sacrificial layer away from the substrate, an orthographic projection of the third pillar body on the substrate is located in an orthographic projection of the third extension layer on the substrate, and the third pillar body and the third extension layer constitute a dam structure.

20. The manufacturing method for the display panel according to claim 19, wherein the manufacturing method for the display panel further comprises:
forming an interlayer dielectric layer, wherein the interlayer dielectric layer includes a blocking recess, and the blocking recess is located in the isolation region;
forming a first source-drain metal layer, wherein the first source-drain metal layer is located on the interlayer dielectric layer and partially located in the blocking recess;
forming a passivation layer, wherein the passivation layer is located on a side of the first source-drain metal layer away from the interlayer dielectric layer and partially located in the blocking recess; and
forming the third pillar body includes: forming a portion of the third pillar body in the blocking recess.
